(19) United States
(12) Patent Application Publication
(10) Pub. No.: US 2011/0146748 A1
(43) Pub. Date: Jun. 23, 2011

(54) SOLAR CELL-STRING

(75) Inventors: Ingram Eusch, Villach (AT); Rudolf Frank, Pischeldorf (AT); Armin Kogler, Treibach (AT)

(73) Assignee: Kioto Photovoltaics GmbH

(21) Appl. No.: 12/943,265

(22) Filed: Nov. 10, 2010

(30) Foreign Application Priority Data
Dec. 22, 2009 (EP) EP 09 015 833.8

(51) Int. Cl. H01L 31/042

(52) U.S. Cl. 136/244

(57) ABSTRACT

The invention concerns to a solar cell-string, wherein a “string” describes a series of solar cells which are connected by electrical conducting strips.

### FIELD OF THE INVENTION

The invention concerns a solar cell-string, wherein a “string” describes a multitude of solar cells connected with each other by electrically conductive strips.

### BACKGROUND OF THE INVENTION

Correspondingly a known solar cell-string comprises the following features:
The string presents a multitude of solar cells arranged with a distance one after the other,
adjacent solar cells are connected by at least two electrical conductor tracks (conductive paths),
each conductor track is with a first section firmly connected to an upper surface of a solar cell and with a second section firmly connected to a lower surface of the adjacent solar cell.
   Usually a pair (2) of conductor tracks is connecting the upper surface of a solar cell with a lower surface of an adjacent solar cell. At the beginning and/or end of the string electrical connections are provided.

Usually the conductor tracks comprise a base body and a solderable coating. The conductor tracks are in these cases soldered onto the solar cells.

To process single solar cells with conductive paths to a complete solar cell-string different processing stages and processing steps are necessary. Thereby it is essential to ensure an exact positioning of the single solar cells and the single conductive paths, so that also the combination of a series of solar cells with a series of conductor tracks takes place in the desired and necessary orientation (arrangement). This is difficult inter alia because the solar cells are extremely thin (approximately 200 μm) and brittle and the conductor tracks with a width of for example 0.5 to 3 mm and a thickness of not more than 0.2 to 1 mm are slender ribbons, that cannot be brought into the desired surface contact with the upper/lower surface of the solar cells so easily.

It is known to transport the conductor tracks through a suction device to the solar cell and place them there, as well as subsequently to fix them by a holding down device onto the solar cells, also during the subsequent soldering process. The hold down clamps are being lifted again only after the respective solar cell has left the soldering station.

An according device with a holding down device is known from DE 10 2006 007 447 A1. The holding down device consists of a frame that has bearing surfaces on both its edge sections, that are supported by conveyor belts in the operating position and have a window in which or next to which down-holding heads are arranged that each have a down-holding pin and are mounted pivotable at the frame. The pins press onto the conductive path when the holding down device is superimposed onto the conductive path thereby pressing the conductor track onto the solar cell. Thereby it is important that the force with which the conductor tracks are fixed is only effective in one direction. Said pins are being supported in so called down-holding heads that are hinged pivotably at the frame.

The known holding down device is very complex in terms of construction; the pins lead to very small pressure-points, wherein the conductor track can easily be damaged. Furthermore an adjustment of the compressive force with respect to the surface of the conductor track is impossible and can incidentally only be done individually through the down-holding heads. As a result the known solar cell-string has no sufficient surface connection between conductor track and solar cell.

### SUMMARY OF THE INVENTION

The object of the invention is to provide a solar cell-string with an optimized connection of conductor track and solar cell.

The solar cell-string according to the invention differs from the known string in that each conductor track has, on its first section, a series of spherically shaped indentations at a distance to each other.

“Spherically shaped” (calotte like) means that the indentation is no unidirectional indentation (in the technical sense) as obtained by a needle as in the state of the art, but describes an indentation in the conductor track that extends over a certain surface area of the conductive path.

This requires holding down devices with according geometry, for example spherically bodies, ball or oval shaped, mounted to the end portion of springs, that press on the conductor track causing corresponding three-dimensional indentation (the spherically shaped indentation) in the conductor track. The ratio of depth (vertical to the conductor track surface) to width (largest width parallel to the conductor track-surface) is typically <1:1, for example <1:2 or <1:3 or <1:5 or <1:7 or <1:10. In the case of an acicular prick the ratio is >1:1.

Preferably the indentation extends completely within the according conductor track, that means the indentation extends just until shortly before the edge of the according surface of the conductor track.

The term “spherically shaped indentation” includes in its most general meaning indentations with planar surfaces; however indentations with curved wall sections (zones) are preferred, because the accordingly formed pressure-bodies exert forces in different directions on the conductive path, so that both the effect of the press-on (hold down) and the subsequent connection of conductor track and solar cell surface is improved.

The press-on of the conductor track onto the solar cell can additionally be improved if a press-on body is used, that has a profiled (textured) surface by which an indentation is formed that has a correspondingly structured (textured) surface for example a latticed wall section.

Thereby various compression forces in different pressure directions are transmitted by the holding down device onto the conductor track and from the conductor track onto the solar cells, so that the solder connection during the subsequent soldering process is sustainably improved, in particular a substantially higher surface contact between conductor track and solar cell is achieved, which is important for the electrical conduction.

As explained above the concrete geometry of the indentation is in particular dependent of the geometry of the holding down device that is being held more ore less stationary relative to the conductor track during the press-on step. Insofar the indentation can for example have a circular cross-section in the area of the free surface of the associated conductive path, but also an oval cross-section or a cross-section with evolvent-like edges.

The height of the indentation (vertically to the surface of the solar cell) is dependent from the thickness of the conductor track, the compressive force with which the holding down device is pressing onto the conductor track as well as the geometry of the pressure body. Usually the maximum height of the indentation (vertically to the surface of the solar cell and conductor track) corresponds to a maximum of 70% of the overall thickness of the conductor track (viewed in the same direction as the indentation) wherein a value of 10% is sufficient to obtain the desired pressure distribution. Typical values are 10-50% or 10-30%.

The distance of the indentations (in longitudinal direction of the corresponding conductor track) is according to one embodiment between 1.0 to 3.0 cm.

The cross-section of the indentation at the free surface of the conductor track is in particular 0.5 to 5 mm² with common values of 0.5 to 2 mm².

Further features of the invention result from the features of the sub-claims as well as the other application documents.

The invention is explained in more detail below by one embodiment.

### BRIEF DESCRIPTION OF THE DRAWINGS

This shows, each in schematic representation:

FIG. 1: A lateral view of a solar cell-string,

FIG. 2: A topview onto a solar cell of the string,

FIG. 3: A topview of a conductor track of the solar cell according to FIG. 2,

FIG. 4: A cross section of the conductor track according to FIG. 3,

FIG. 5: A lateral view of a holding down device.

In the figures components which are similar or with similar effects are represented with identical characters.

### DETAILED DESCRIPTION OF THE INVENTION

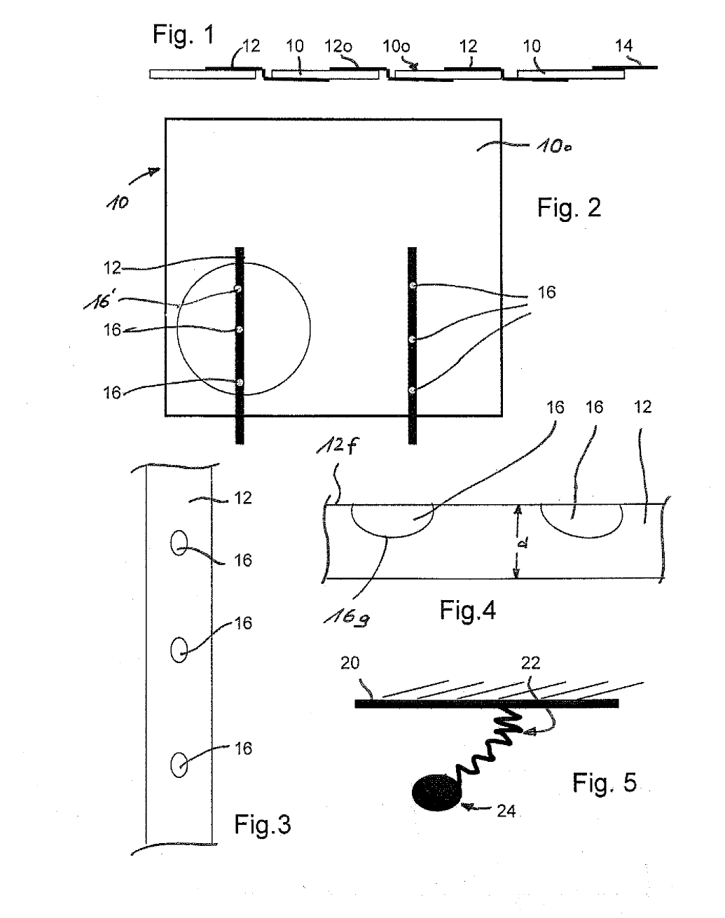

FIG. 1 shows—strongly schematic—a solar cell-string made of four solar cells 10, that are connected by conductor tracks 12, wherein each conductor track is firmly connected with a first section 12o to an upper surface 10o of a solar cell 10 and with a second section 12u to a lower surface 10u of the adjacent solar cell 10, by soldering.

Electric connections at the end-face are schematically represented by numeral 14.

FIG. 2 shows a topview onto a solar cell 10 according to FIG. 1 wherein two conductor tracks 12 being parallel to one another with a clearance between them are extending across the upper surface 10o of the solar cell 10 can be seen.

FIG. 3 shows in an enlarged scale compared with FIG. 2, but also only schematic, spherically-shaped indentations 16 between edges 12r of the conductor track 12. The indentations 16 extend centered within the conductor track 12. This results in a very good pressure distribution when depressing with the according holding down device (FIG. 5) and by that a good contact pressure of the conductor track 12 onto the solar cell 10.

In the top view the spherical-shaped indentations 16 have approximately an oval cross-section. The distance between adjacent indentations 16 is approximately 3 to 5 times of the opening width of the indentation 16 within the area of the free upper surface 12f of the conductor track 12.

FIG. 3 shows the area of the spherically-shaped indentations 16 in a cross-sectioned view. The curved edges 16g of the indentations 16 can be seen, wherein the maximum height of the indentations 16 is in this case approximately half the thickness d of the conductor track 12. The indentation 16 shown in FIG. 4 on the right is slightly tilted with respect to the indentation displayed on the left, which is supposed to clarify that the indentions 16 not always have an exactly symmetrical geometry under the given technical conditions and not always an exactly centered position on the conductive path, but can also, as in 16′ in FIG. 2, extend somewhat eccentric.

Despite this it is desired that the indentations 16 extend completely within the corresponding conductor track that means being circumferentially limited by the free upper surface 12f of the conductor track 12.

Together with the curved edges this results in an optimized pressure distribution with the aid of the corresponding holding down device during transport and subsequent soldering process.

FIG. 5 shows and embodiment of a possible holding down device. At a crossbeam 20 a spiral-spring 22 is hinged that bears a spherical body mounted at its free end, in this case shaped as a ball. Body 24 is made of glass fiber reinforced polymer that is resistant up to 400° C., alternatively from ceramic/porcelain with a temperature resistance >400° C. The material of the body 24 can therefore be applied in a soldering station without any problem. Body 24 which presses over a certain area onto an according soldering strip (a conductor track 12) allows a multidimensional force distribution onto the conductor track 12 under the influence of the spring 22, or onto the corresponding solar cell-string respectively, where groove (indentation) 16, shown in FIG. 4 in a cross-section results, from which body 24 can be removed without any problem after the soldering process. With respect to the desired compressive force it is advantageous if the body is arranged eccentrically to the mounting of the spring 22 and the crossbeam 20, as shown in FIG. 5, therefore not only developing an unidirectional force as in the case of a pure vertical load onto the conductor track 12.

Obviously a series of holding down devices identified above are arranged at the crossbeam 20 to produce a multitude of corresponding press-on areas available on the according conductor track sections.

Having described the invention, the following is claimed:

1. Solar cell-string comprising:
a string providing several solar cells arranged with a distance to each other one behind the other,
adjacent solar cells are in each case connected by at least two conductor tracks,
each conductor track is firmly connected with a first section to an upper surface of a solar cell and with a second section to a lower surface of the adjacent solar cell,
each conductor track has at its first section a series of spherically-shaped indentations, arranged with a distance to each other.

2. Solar cell-string according to claim 1, with at least one indentation extending completely within the corresponding conductor track.

3. Solar cell-string according to claim 1, wherein at least one indentation has curved zones.

4. Solar cell-string according to claim 1, wherein at least one indentation has a profiled wall section.

5. Solar cell-string according to claim 1, wherein at least one indentation in the area of the free upper surface of the corresponding conductor track has a circular cross-section.

6. Solar cell-string according to claim 1, wherein at least one indentation in the area of the free upper surface of the corresponding conductor track has an oval cross-section.

7. Solar cell-string according to claim 1, wherein at least one indentation in the area of the free upper surface of the corresponding conductor track has an evolvent like shaped cross-section.

8. Solar cell-string according to claim 1, wherein the indentations have a distance of 1.0 to 3.0 cm to each other.

9. Solar cell-string according to claim 1, wherein the indentations have a height, perpendicular to the surface of the conductor track that is 0.1 to 0.7 of the thickness of the conductor track perpendicular to the conductor track surface.
